(19) United States
(12) Patent Application Publication
(10) Pub. No.: US 2024/0222295 A1
(43) Pub. Date: Jul. 4, 2024

(54) STACKED INORGANIC-ORGANIC DIELECTRICS FOR THIN FILM CAPACITORS IN PACKAGE SUBSTRATES

(71) Applicant: Intel Corporation, Santa Clara, CA (US)

(72) Inventors: Mahdi Mohammadighaleni, Phoenix, AZ (US); Joshua Stacey, Chandler, AZ (US); Benjamin T. Duong, Phoenix, AZ (US); Thomas S. Heaton, Mesa, AZ (US); Dilan Seneviratne, Phoenix, AZ (US); Rahul N. Manepalli, Chandler, AZ (US)

(73) Assignee: Intel Corporation, Santa Clara, CA (US)

(21) Appl. No.: 18/148,598

(22) Filed: Dec. 30, 2022

(51) Int. Cl. H01L 23/64; H01G 4/20; H01G 4/33; H01L 23/00; H01L 23/498; H05K 1/16

(52) U.S. Cl. CPC H01L 23/642; H01G 4/206; H01G 4/33; H01L 23/49822; H01L 23/49838; H01L 24/16; H05K 1/162; H01L 2224/16235; H01L 2924/19041; H05K 2201/0175

(57) ABSTRACT

Embodiments described herein enable a microelectronic assembly that includes: a package substrate having a core including a solid continuous glass material with one or more capacitors in the solid continuous glass material and integrated circuit (IC) dies coupled to the package substrate. The structure of each capacitor includes a dielectric structure between two conductive structures. The dielectric structure comprises a layer of organic dielectric material between two layers of crystalline inorganic material. The crystalline inorganic material is in direct contact with one of the two conductive structures.

### TECHNICAL FIELD

The present disclosure relates to techniques, methods, and apparatus directed to stacked inorganic-organic dielectrics for thin film capacitors (TFCs) in package substrates.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional views of an example microelectronic assembly according to some embodiments of the present disclosure.

FIG. 2A is a schematic cross-sectional view of a capacitor in a portion of an example microelectronic assembly according to some embodiments of the present disclosure.

FIG. 2B is a schematic plan view of the capacitor of FIG. 2A.

FIG. 3A is a schematic cross-sectional view of a capacitor in a portion of another example microelectronic assembly according to some other embodiments of the present disclosure.

FIG. 3B is a schematic plan view of the capacitor of FIG. 3A.

FIG. 4 is a schematic cross-sectional view of a portion of another example microelectronic assembly according to some other embodiments of the present disclosure.

FIGS. 5A-5G are schematic cross-sectional views of various stages of manufacture of an example package substrate according to some other embodiments of the present disclosure.

FIG. 6 is a cross-sectional view of a device package that includes one or more microelectronic assemblies in accordance with any of the embodiments disclosed herein.

FIG. 7 is a cross-sectional side view of a device assembly that includes one or more microelectronic assemblies in accordance with any of the embodiments disclosed herein.

FIG. 8 is a block diagram of an example computing device that includes one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

Decoupling capacitors are used in electronic circuits that supply current to IC dies during transient spikes in power demand and to minimize power supply noise. Power delivery requirements for server processors and other advanced processing platforms include an increasing demand for more decoupling capacitance close to the IC die to prevent voltage droop on voltage rails. This capacitance may not be supplied by discrete surface mounted capacitors because of the high-inductance path and increased packaging area. Further, the additional on-die metal-insulator-metal (MIM) capacitors that would be required to meet this demand is high and is not effective at high frequencies due to high equivalent series resistance (ESR).

One solution for providing the needed decoupling capacitance is to integrate a capacitive layer into the package substrate below the IC die. Ex situ fabricated decoupling TFC sheets can be purchased and embedded into the package substrate by pick-and-place techniques at the die-level. However, using ex situ fabricated decoupling TFC sheets is costly and limits design flexibility. On the other hand, in situ fabricated capacitors in package substrates tend to use high dielectric constant inorganic materials in the capacitors, although organic dielectric materials may also be used in specific applications. Crystalline inorganic materials have high dielectric constant, but also high leakage due to small bandgap or low dielectric strength (i.e., breaking down at lower voltages). Amorphous dielectrics such as organic polymers have lower leakage but also lower dielectric constant. In addition, the manufacturing processes for various such organic or inorganic dielectric materials typically involve high temperatures that are not compatible with electronic circuitry or materials used therewith, tending to severely limit the choice of materials available for fabricating in situ capacitors.

Accordingly, embodiments described herein provide for sandwiching a polymeric dielectric thin film between crystalline inorganic dielectric thin films through vapor deposition to form high aspect ratio capacitors with high capacitance and low leakage for high-voltage applications. A “thin film” as used herein refers to a layer of materials ranging in thickness from a few tens of nanometers to a few tens of micrometers. The thin film may be as thin as one layer of atoms. In general, the thickness of the thin film is measurable in the same or a lesser order of magnitude compared to the scale of length that is intrinsic to the measured system. Various embodiments as disclosed enable a microelectronic assembly that includes: a package substrate having a core including a solid continuous glass material with one or more capacitors in the solid continuous glass material and IC dies coupled to the package substrate. The structure of each capacitor includes a dielectric structure between two conductive structures. The dielectric structure comprises a layer of organic dielectric material between two layers of crystalline inorganic material. The crystalline inorganic material is in direct contact with one of the two conductive structures.

Embodiments described herein are directed to a TFC in a package substrate and techniques of fabricating such a TFC in situ with the package substrate. Such a TFC may sometimes be referred to as an in situ TFC herein. Embodiments of the in situ TFC described herein are fabricated in a package substrate, unlike an ex situ TFC that is fabricated independently of the package substrate.

In another embodiment, the microelectronic assembly comprises: a package substrate having a core including a solid continuous glass material with one or more capacitors in the solid continuous glass material; and one or more IC dies coupled to the package substrate. At least one of the capacitors comprises: a first tubular layer comprising a metallic material, the first tubular layer having an outer surface and an inner surface, the outer surface in contact with the glass material; a second tubular layer concentric with the first tubular layer and in contact with the inner surface of the first tubular layer, the second tubular layer comprising a first dielectric material; a third tubular layer concentric with the second tubular layer and in contact with the second tubular layer, the third tubular layer comprising a second dielectric material; a fourth tubular layer concentric with the third tubular layer and in contact with the third tubular layer, the fourth tubular layer comprising the first dielectric material; and a fifth tubular layer concentric with the fourth tubular layer and in contact with the fourth tubular layer, the fifth tubular comprising the metallic material.

In another embodiment is disclosed herein a substrate, comprising: a core including a solid continuous glass material, the core having a first surface and an opposing second surface and a capacitor in the solid continuous glass material; layers of a first organic dielectric material on at least one side of the core, the layers being parallel to the first surface and the second surface; conductive traces between the layers of the first organic dielectric material, the conductive traces being parallel to the first surface and the second surface; and conductive vias through the layers of the first organic dielectric material, the conductive vias being perpendicular to the first surface and the second surface. The capacitor comprises a dielectric structure between two conductive structures, the dielectric structure comprises a second organic dielectric material between two inorganic dielectric materials, and the two conductive structures are conductively coupled to the conductive traces.

In other embodiments, a capacitor structure is disclosed, comprising: a first conductive structure of a metallic material; a second conductive structure of the metallic material; and a dielectric structure between the first conductive structure and the second conductive structure. The dielectric structure comprises: a first layer of crystalline inorganic material; a second layer of the crystalline inorganic material; and a layer of organic dielectric material between the first layer and the second layer.

In various embodiments, a method comprises: providing a glass panel with cavities, the glass panel having a top surface and a bottom surface; depositing a first layer of metallic material on the glass panel so as to conformally coat the top surface, the bottom surface and surfaces of the cavities; depositing a second layer of inorganic dielectric material over the first layer; depositing a third layer of organic dielectric material over the second layer; depositing a fourth layer of the inorganic dielectric material over the third layer; depositing a fifth layer of the metallic material over the fourth layer so as to fill the cavities completely; and planarizing surfaces of the glass panel such that none of the metallic material, the inorganic dielectric material or the organic dielectric material coats the top surface or the bottom surface of the glass panel.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a solid continuous silicon (or other solid continuous semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group Ill of the periodic table (e.g., Al, Ga. In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may comprise a semiconductor material including, for example, N-type or P-type materials. The PIC may include, for example, a crystalline base material formed using a solid continuous silicon (or other solid continuous semiconductor material) or an SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may comprise a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In SOI, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B203, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and PCBs such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photo-imageable polymers, dry film photo-imageable polymers, acrylics, solvents) may be provided in an IC package described herein and may not be labeled or shown to avoid cluttering the drawings. Solder resist may be a liquid or dry film material including photo-imageable polymers. In some embodiments, solder resist may be non-photo-imageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

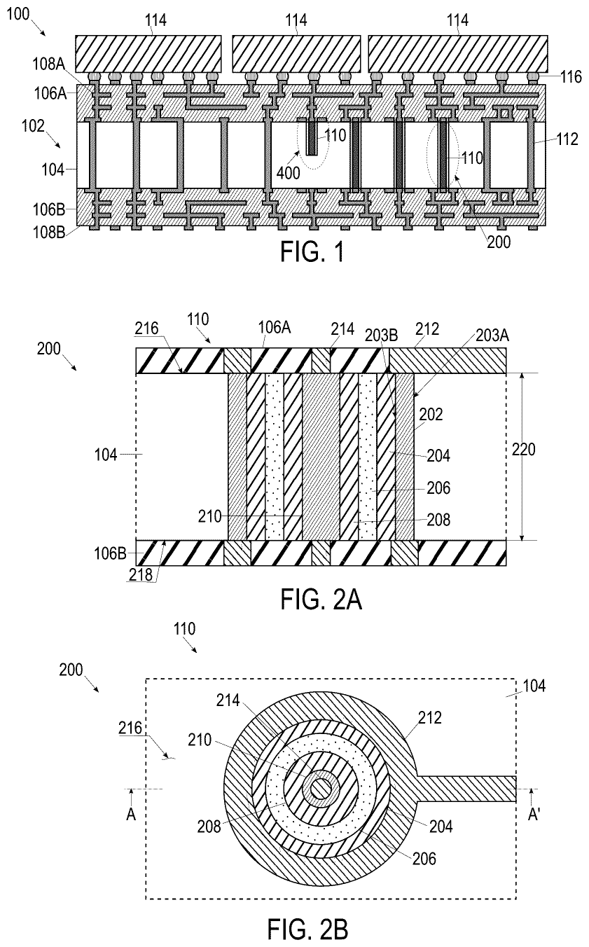

FIG. 1 is a schematic cross-sectional view of an example microelectronic assembly 100 according to some embodiments of the present disclosure. Microelectronic assembly 100 comprises a package substrate 102 having a core 104 comprising solid continuous glass material. “Solid continuous glass material” refers to a continuous volume of solid glass material, such as a glass plate, as opposed to a volume containing broken pieces of glass material, such as glass-fiber-reinforced epoxy. In some embodiments, the glass material may comprise fused quartz. In some embodiments, the glass material may comprise borosilicate glass, for example, including silica (e.g., 52%-56%), alumina (e.g., 12%-16%), borate (e.g., 5%-10%), calcinate (e.g., 16%-25%), and magnesium oxide (e.g., 0%-6%). In some embodiments, the glass material may have a composition to enable a low coefficient of thermal expansion (CTE), for example, around 2.8 PPM/C; in some such embodiments, the glass material may comprise approximately 60%-65% silica and 20%-25% alumina. In some other embodiments, the glass material may have a composition to enable low electrical loss, for example, with dielectric constant around 4.8 at 1 GHz and 4.69 at 10 GHZ, and loss tangent of 0.0043 at 1 GHz; in some such embodiments, the glass material may comprise approximately 52%-56% silica, 10%-15% alumina, 15%-20% borate, 0%-10% calcinate, and 0%-5% magnesium oxide. The solid continuous glass material may fill substantially all available continuous volume of core 104 (i.e., the glass material is not in the form of fiber-reinforced epoxy). Generally, as used herein, the term “glass” refers to an inorganic material, and does not refer to organic polymer materials.

In various embodiments, package substrate 102 may further include layers of an organic material 106 on one or either side of core 104. In the example embodiment shown, organic material 106 is on either side of core 104 and is labeled as 106A and 106B to distinguish them suitably. Examples of organic material 106 include epoxy and/or polyimide materials typically used in package substrates as listed in the previous subsection (e.g., polyimide, epoxy mold, etc.). In some other embodiments, organic material 106 may be only on one side of core 104. Conductive structures 108 may be disposed in organic material 106. Conductive structures 108 may include conductive traces between the layers of organic material 106 and conductive vias through the layers of organic material 106. In the example embodiment shown, conductive structures 108 is on either side of core 104 and is labeled as 108A and 108B to distinguish them suitably.

In various embodiment, one or more capacitors 110 may be provided in the solid continuous glass material of core 104. In some embodiments, capacitors 110 may comprise in situ high aspect ratio TFCs fabricated in core 104 and having organic-inorganic stacked dielectric thin films between conductive structures. In various embodiments, capacitors 110 may be advantageously used in microelectronic packaging for high voltage applications, for example, by providing low current leakage and high capacitance. The dielectric material stack of capacitors 110 as described in further detail in succeeding figures can enable high capacitance and low leakage at high voltages (e.g., approximately 20V or less).

In some embodiments, conductive through-glass vias (TGVs) 112 in core 104 may conductively coupled conductive structures 108A and 108B on either side of core 104. In some other embodiments, TGVs 112 may be absent. In some embodiments, capacitors 110 may extend through the entirety of the thickness of core 104, extending fully between the two opposing sides of core 104. In some other embodiments, capacitors 110 may extend partially through the thickness of core 104. In yet other embodiments, some capacitors 110 may extend completely through the thickness of core 104 and some other capacitors 110 may extend partially through the thickness of core 104. One or more IC dies 114 may be coupled to package substrate 102 by suitable interconnects 116. In some embodiments, interconnects 116 may be mid-level interconnects (MLI); in other embodiments, interconnects 116 may be SLI; in yet other embodiments, interconnects 116 may be FLI. Examples of MLI, SLI and FLI are listed in the previous subsection.

In various embodiments, unlike traditional in situ TFCs in package substrates that are oriented parallel to a planar interface between the package substrate and the IC die coupled thereto, capacitors 110 in package substrate 102 are oriented perpendicular to the planar interface between package substrate 102 and IC dies 114. To explain further, a general capacitor consists of a dielectric material between two conductive structures. In traditional TFCs, the two conductive structures are oriented parallel to the planar interface between the package substrate and the IC dies coupled thereto, so that one conductive structure of the capacitor is closer to the planar interface than the other conductive structure. In other words, the intrinsic length (or width) of the TFC is measured in a direction parallel to the planar interface while the intrinsic thickness is measured perpendicular to the planar interface. In capacitors 110 on the other hand, because of their orientation perpendicular to the planar interface between package substrate 102 and IC dies 114, both conductive structures of each one of capacitors 110 are equidistant from the planar interface between package substrate 102 and IC dies 114. The intrinsic length (or width, diameter, etc.) of capacitors 110 is measurable parallel to the planar interface while the intrinsic thickness of capacitors 110 is measurable perpendicular to the planar interface.

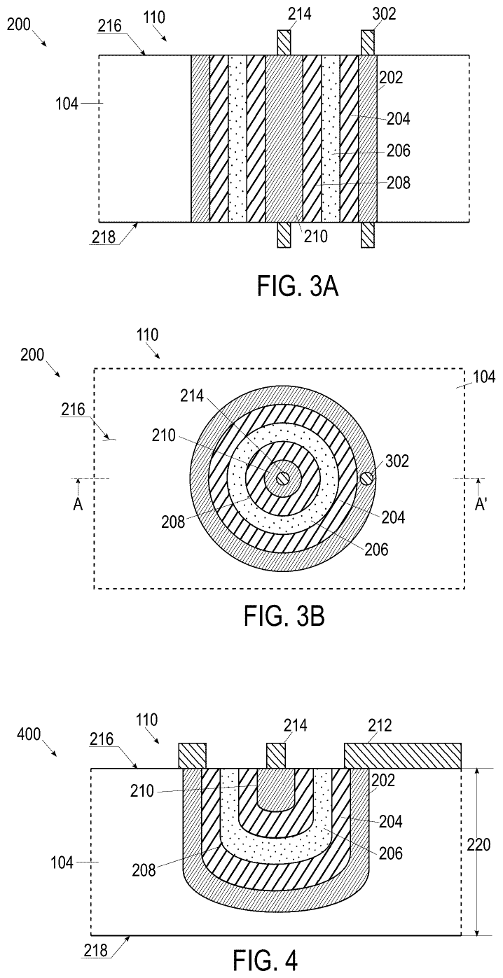

A detailed view of a portion 200 of microelectronic assembly 100, comprising an example capacitor 110 is shown in the side view of FIG. 2A. Capacitor 110 includes: a layer 202 comprising a metallic material, layer 202 having a first surface 203A and a second surface 203B opposite to first surface 203A. First surface 203A is in contact with the glass material of core 104. Examples of the metallic material include copper, iridium, iridium oxide, ruthenium, ruthenium oxide, titanium nitride, and other such low resistivity metals. In various embodiments, layer 202 may be formed by atomic layer deposition (ALD) and may have corresponding thickness (e.g., in a range of several tens of nanometers) according to the manufacturing settings of the ALD process.

Another layer 204 is in contact with second surface 203B of layer 202, layer 204 comprising an crystalline inorganic dielectric material. Some examples of crystalline inorganic dielectric material include titanium oxide, hafnium oxide and zirconium oxide. Other examples include hafnium silicon oxide, lanthanum oxide, lanthanum aluminum oxide, zirconium silicon oxide, hafnium zirconium oxide, tantalum oxide, barium strontium titanium oxide, barium titanium oxide, strontium titanium oxide, yttrium oxide, aluminum oxide, lead scandium tantalum oxide, and lead zinc niobate. Crystalline inorganic dielectric materials with high dielectric constant (e.g., dielectric constant greater than 10) that can be deposited as thin films at relatively low temperatures without annealing are suitable choices for the crystalline inorganic dielectric material of layer 204.

Yet another layer 206 is in contact with layer 204, layer 206 comprising an amorphous organic dielectric material. Note that the layers shown have two opposing surfaces each, but only the surfaces of layer 202 are labeled so as not to clutter the drawing. Examples of the amorphous organic dielectric material of layer 206 include polymers such as polytetrafluoroethylene (PTFE), poly (1,3,5-trimethyl-1,3,5-trivinyl cyclotrisiloxane) (pV3D3), poly (1,3,5,7-tetravinyl-1,3,5,7-tetramethylcyclotetrasiloxane) (pV4D4). Amorphous organic polymers that can be deposited as thin films are suitable material choices for the organic dielectric material of layer 206. In various embodiments, the amorphous organic dielectric material of layer 206 may have a lower dielectric constant than the crystalline inorganic dielectric material of layer 204. In various embodiments, the amorphous organic dielectric material of layer 206 may have lower leakage and wider energy gap characteristics than the crystalline inorganic dielectric material of layer 204. Note that the amorphous organic dielectric material of layer 206 may be different from the organic material 106 on either side of core 104 of package substrate 102.

Yet another layer 208 is in contact with layer 206, layer 208 comprising the crystalline inorganic dielectric material of layer 204. Yet another layer 210 is in contact with layer 208, layer 210 comprising the metallic material of layer 202. Thus, layer 206 comprising the low-k amorphous organic dielectric material is sandwiched between two layers of the high-k crystalline inorganic dielectric material. Such a dielectric structure may allow for high capacitance values for capacitor 110 while also providing low leakage in high-voltage applications from the amorphous organic dielectric material. Such a structure has advantages over using only high-k crystalline inorganic dielectric materials by providing low leakage characteristics. Such a structure has advantages over using only low-k amorphous organic dielectric materials by providing higher dielectric constant and high capacitance from the crystalline inorganic dielectric materials. In various embodiments, encapsulating or sandwiching the amorphous organic dielectric material between two crystalline inorganic dielectric materials can reduce the leakage current of high-k materials at higher voltages because amorphous organic films have high energy gaps, and the polymer chain growth direction is lateral on the surface; such a materials stack (i.e., comprising stacked inorganic dielectric materials and organic dielectric material) can enable high capacitance (e.g., 10-100 nF/mm²) and low leakage (e.g., less than 10⁻³ A at voltages in a range between 2V and 8V) at high voltages (e.g., 2V-8V). In some such embodiments, the planar dielectric capacitance of dielectric structures comprising layers 204, 206 and 208 may be in a range approximately between 10 nF/mm² and 100 nF/mm²) (e.g., 40 nF/mm²).

Capacitor 110 may be in contact with organic material 106 in some embodiments. In the example shown, capacitor 110 is in contact with organic material 106A and 106B on either side of core 104. Layers 202 and 210 comprising the metallic material may operate as the two electrodes of capacitor 110. Layer 202 may be in conductive contact with conductive structures 108, for example, conductive trace 212 as shown in the figure. Layer 210 may be in conductive contact with other conductive structures 108, for example, conductive via 214 as shown in the figure. Core 104 may have two opposing surfaces 216 and 218. Layers of organic material 106A may be disposed on surface 216 and layers of organic material 106B may be disposed on surface 218 in the example embodiment shown. A perpendicular distance between surfaces 216 and 218 may indicate thickness 220 of core 104. In the example embodiment shown, capacitor 110 extends fully through thickness 220 of core 104.

In some embodiments, capacitor 110 may have a circular shape in plan view as shown in FIG. 2B. Organic material 106 is not shown in FIG. 2B for clarity of explanation. Capacitor 110 may be surrounded by the glass material of core 104 in the plan view. In some embodiments, layers 202, 204, 206 and 208 may comprise tubular concentric structures, and layer 210 may comprise a solid cylinder. Thus, in the plan view, layers 202, 204, 206 and 208 may have annular (e.g., ring-shaped) cross-section, and layer 210 may have a circular cross-section. Note that various other shapes are also contemplated within the broad scope of the present disclosure. For example, layers 202, 204, 206, 208 and 210 may comprise parallel plate structures that are rectangular in plan view; in another example, layers 202, 204, 206, 208 and 210 may comprise tubular structures that are polygonal (e.g., hexagonal, octagonal) in plan view. The side cross-sectional view of FIG. 2A may be taken along a plane AA′ as indicated in FIG. 2B; thus, layers 202-208 are symmetrical around layer 210 in FIG. 2A.

In the example embodiment shown in FIGS. 2A-2B, conductive trace 212 is an annular ring in direct contact with (tubular) layer 202. The annular ring may be suitably connected to a straight trace in some embodiments. Conductive via 214 may be in direct contact with (cylindrical) layer 210. Conductive via 214 may be directly connected to another conductive trace in another layer of organic material 106A, and not shown in the figure. In various embodiments, conductive trace 212 may be conductively coupled to a first voltage (e.g., Vₛₛ) and conductive via 214 may be conductively coupled to a second voltage (e.g., V_{dd}), the first voltage being different from the second voltage. In some embodiments, the voltage differential between the first voltage and the second voltage may be approximately 20V. In other embodiments, the voltage differential between the first voltage and the second voltage may be less than 20V. Note that conductive trace 212 and conductive via 214 are in organic material 106 (e.g., 106A in the figure). In various embodiments, analogous conductive structures 108 may be disposed on surface 218 of core 104 and suitably conductively coupled to layers 202 and 210 of capacitor 110.

In some examples, core 104 may have a thickness of 0.2 millimeters. In some examples, the dielectric structure including layers 204, 206 and 208 may have a thickness of approximately between 20 nanometers and 50 nanometers. In some examples, the diameter of capacitor 110 (measured across the total thickness of capacitor, i.e., diameter of first surface 203A) may be approximately between 0.02 millimeters and 0.1 millimeters. In some embodiments, the pitch of capacitors 110 in core 104 may vary between 0.05 millimeters and 0.20 millimeters. In various embodiments, the number of capacitors 110 in one square millimeter of core 104 may vary between 40 and 500, depending on the diameter and pitch of capacitors 110, and the capacitance desired. The number and size of capacitors 110 may be varied according to the package area capacitance desired. For example, to obtain a package area capacitance of approximately 250 nF/mm², capacitors with diameters of approximately 0.025 millimeters at a pitch of 0.05 millimeters may be used; whereas to obtain a package area capacitance of approximately 110 nF/mm², capacitors with diameters of approximately 0.01 millimeters at a pitch of 0.15 millimeters may be used.

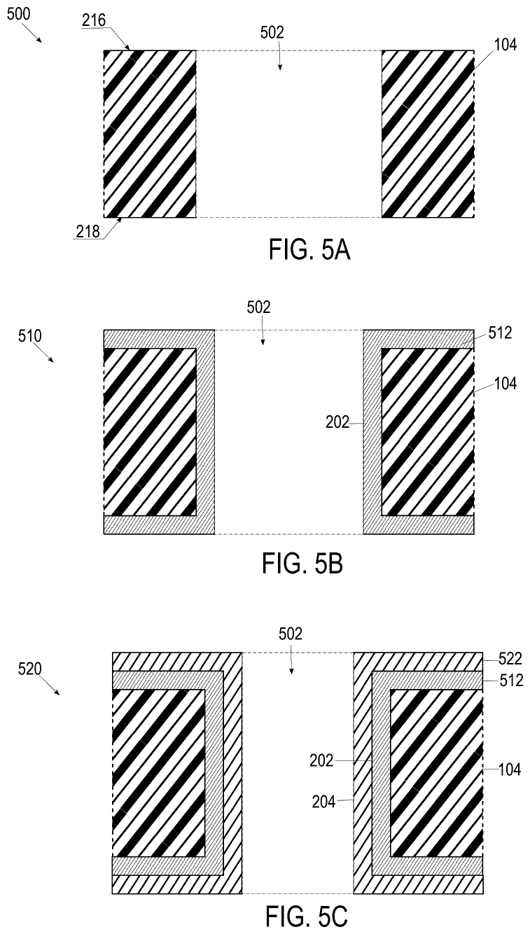

FIGS. 3A and 3B are a simplified cross-sectional view and plan view respectively of another embodiment of capacitor 110 in portion 200 of microelectronic assembly 100. In the embodiment shown, the conductive structures in direct contact with layers 202 and 210 may be different from that of FIGS. 2A-2B. For example, instead of a conductive trace, conductive vias 302 and 214 may be in direct contact with layers 202 and 210 respectively. Conductive vias 302 and 214 may be conductively coupled to conductive traces in other layers that are not shown in the figure. Organic material 106 is also not shown in the figure for ease of illustration and explanation. The structure may be clarified in the plan view shown in FIG. 3B. In the figure, only one conductive via 302 is shown in direct contact with layer 202. In various embodiments, any number of conductive vias 302 may be in direct contact with layers 202 or 210 as can be accommodated by manufacturing processes and other considerations beyond the scope of the present disclosure.

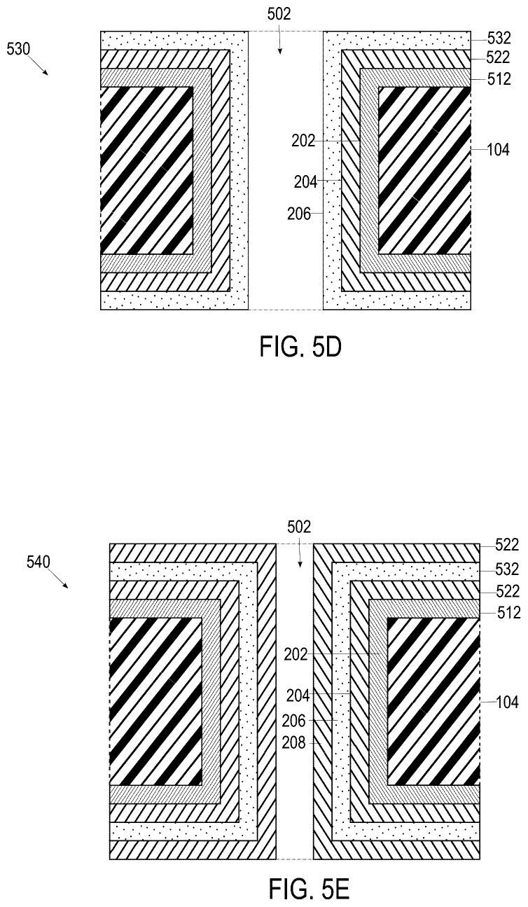

FIG. 4 is a simplified cross-sectional view of another embodiment of a portion 400 of microelectronic assembly 100 of FIG. 1. In the embodiment shown, capacitor 110 extends partially through thickness 220 of core 104. As shown in the figure, layers 202, 204, 206, 208 and 210 may have U-shaped cross-sections with the exact shape and curvature of the bottom portion determined by various manufacturing processes such as etching, laser drilling etc. used to form the initial cavities in core 104 in which capacitor 110 is fabricated. In some embodiments, instead of U-shaped cross-sections with smooth corners, layers 202-210 may have angular corners in cross-sectional view, depending on various manufacturing processes. In embodiments where capacitor 110 extends partially through thickness 220 of core 104, layers 202 and 210 may be conductively connected to conductive structures 212 and 214 disposed on one of surfaces 216 and 218 (e.g., in the example shown, layers 202 and 210 are in direct contact with conductive trace 212 and conductive via 214 respectively on surface 216).

In various embodiments, any of the features discussed with reference to any of FIGS. 1-4 herein may be combined with any other features to form a package with one or more IC dies as described herein. For example, in some microelectronic assemblies, some IC dies may be coupled by interconnects having solder and other IC dies may be coupled by non-solder bonds. Some such combinations are described above, but, in various embodiments, further combinations and modifications are possible. Various different embodiments described in different figures may be combined suitably based on particular needs within the broad scope of the embodiments.

### Example Methods

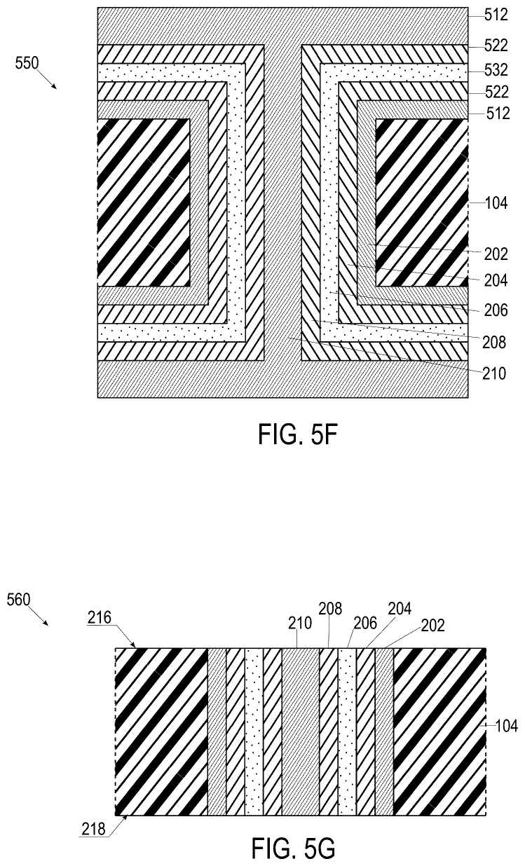

FIGS. 5A-5G are schematic cross-sectional views of various stages of manufacture of example capacitor 110 in microelectronic assembly 100 according to some other embodiments of the present disclosure. FIG. 5A shows a structure 500 comprising a panel of glass, corresponding to core 104 of package substrate 102. The panel of glass includes cavities 502. In the example shown, cavity 502 is a through-hole, extending through the entire thickness of the panel, for example, suitable for fabricating capacitor 110 as shown in the embodiment of FIG. 2A or 3A. In other embodiments, cavity 502 may be a blind cavity, and capacitors 110 fabricated therein may not extend through the entirety of core 104, for example, as shown in the embodiment of FIG. 4. In various embodiments, the panel may be approximately 500 millimeters by 500 millimeters in area, or the size of a standard silicon wafer (e.g., 300 millimeters diameters) or other suitable size appropriate for large volume manufacturing in semiconductor processing facilities. Multiple ones of core 104 may be included in structure 500, and only one such core 104 is shown merely for ease of illustration, and not as a limitation.

FIG. 5B shows a structure 510 subsequent to depositing layer 202 of metallic material 512 as specified in reference to FIG. 2A. In various embodiments, layer 202 may be deposited by ALD processes. Layer 202 forms a conformal coating on the panel of glass, coating all exposed surfaces, including surfaces of cavity 502 substantially uniformly.

FIG. 5C shows a structure 520 subsequent to depositing layer 204 of crystalline inorganic dielectric material 522 as specified in reference to FIG. 2A. Layer 204 forms a conformal coating over layer 202 on the panel of glass, coating all exposed surfaces, including surfaces of layer 202 in cavity 502 substantially uniformly. In various embodiments, controlled thin film deposition of crystalline inorganic dielectric material 522 may be enabled by vacuum-based vapor deposition techniques such as plasma-enhanced chemical vapor deposition (PECVD), sputtering, ALD, and initiated chemical vapor deposition (iCVD). In some embodiments, such processes may be accomplished in the same equipment (e.g., reactor), chamber, or deposition system as the ALD used to deposit layer 202 of metallic material 512. In some embodiments, layer 202 may be deposited by ALD. The ALD process can generate a thin, dense, and conformal film of crystalline inorganic dielectric material 522, and the process allows more control of the thickness and composition of the film than other processes such as sputtering.

FIG. 5D shows a structure 530 subsequent to depositing layer 206 of amorphous organic dielectric material 532 as specified in reference to layer 206 of FIG. 2A. Layer 206 forms a conformal coating over layer 204 on the panel of glass, coating all exposed surfaces, including surfaces of layer 204 in cavity 502 substantially uniformly. In some embodiments, layer 206 may be deposited by iCVD in the same equipment used to deposit layer 204. The iCVD process has several advantageous characteristics over other processes such as parylene deposition systems, molecular deposition system (MLD), PECVD, etc., that makes it a better candidate for the deposition of amorphous organic dielectric material 532. For example, the substrate temperature is lower (e.g., 10-60° C.) than with other processes such as PECVD. The iCVD process also provides pure, pinhole-free thin film, grown directly from the surface of inorganic layer 204. In addition, iCVD can fill nano-porous features in inorganic layer 204, sealing any defects and smoothing the surface.

In various embodiments, in the iCVD process, a monomer of amorphous organic dielectric material 532 is first heated to a suitable temperature. For example, monomer 1,3,5-trimethyl-1,3,5-trivinylcyclotrisiloxane (V3D3) is heated to 40° C. An appropriate initiator such as a thermally activated initiator radical may be heated and vaporized into the reactor chamber. For example, for the V3D3 monomer, tert-butyl peroxide (TBPO) may be used as the initiator. The monomer deposits on the surface of inorganic layer 204 and the initiator initiates the polymerization process. Polymerization occurs laterally along the surface to generate the final composition and molecular structure (e.g., pV3D3 from monomer V3D3) of amorphous organic dielectric material 532 of layer 206.

FIG. 5E shows a structure 540 subsequent to depositing layer 208 of crystalline inorganic dielectric material 522 over layer 206. In various embodiments, layer 208 may be deposited by ALD in a process similar to the deposition of layer 204.

FIG. 5F shows a structure 550 subsequent to depositing layer 210 comprising metallic material 512. In various embodiments, layer 210 may be deposited by electroplating. In the process, cavity 502 may be filled entirely.

FIG. 5G shows a structure 560 subsequent to planarizing surfaces 216 and 218 of core 104 so that metallic material 512, crystalline inorganic dielectric material 522 and amorphous organic dielectric material 532 are removed from surfaces 216 and 218 while retained in erstwhile cavity 502. Layers of organic material 106 and conductive structures 108 may be formed on surfaces 216 and/or 218 using processes in traditional package substrate manufacturing.

Although FIG. 5 illustrates various operations performed in a particular order, this is simply illustrative, and the operations discussed herein may be reordered and/or repeated as suitable. Further, additional processes which are not illustrated may also be performed without departing from the scope of the present disclosure. Also, various ones of the operations discussed herein with respect to FIG. 5 may be modified in accordance with the present disclosure to fabricate others of microelectronic assembly 100 disclosed herein. Although various operations are illustrated in FIG. 5 once each, the operations may be repeated as often as desired. For example, one or more operations may be performed in parallel to manufacture and test multiple microelectronic assemblies substantially simultaneously. In another example, the operations may be performed in a different order to reflect the structure of a particular microelectronic assembly in which one or more substrates or other components as described herein may be included.

Furthermore, the operations illustrated in FIG. 5 may be combined or may include more details than described. For example, the operations may be modified suitably without departing from the scope of the disclosure for IC dies that do not have a semiconductor substrate, but rather, are fabricated on other materials, such as glass or ceramic materials. Still further, the various operations shown and described may further include other manufacturing operations related to fabrication of other components of the microelectronic assemblies described herein, or any devices that may include the microelectronic assemblies as described herein. For example, the operations not shown in FIG. 5 may include various cleaning operations, additional surface planarization operations, operations for surface roughening, operations to include barrier and/or adhesion layers as desired, and/or operations for incorporating microelectronic assemblies as described herein in, or with, an IC component, a computing device, or any desired structure or device.

### Example Devices and Components

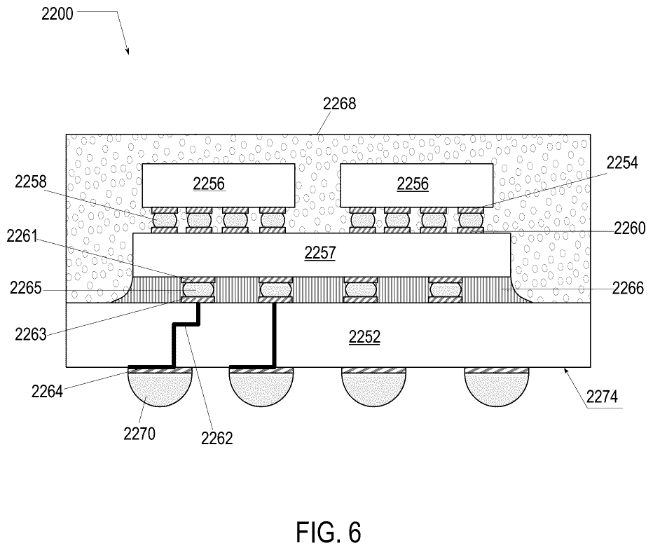

The packages disclosed herein, e.g., any of the embodiments shown in FIGS. 1-5 or any further embodiments described herein, may be included in any suitable electronic component. FIGS. 6-8 illustrate various examples of packages, assemblies, and devices that may be used with or include any of the IC packages as disclosed herein.

FIG. 6 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

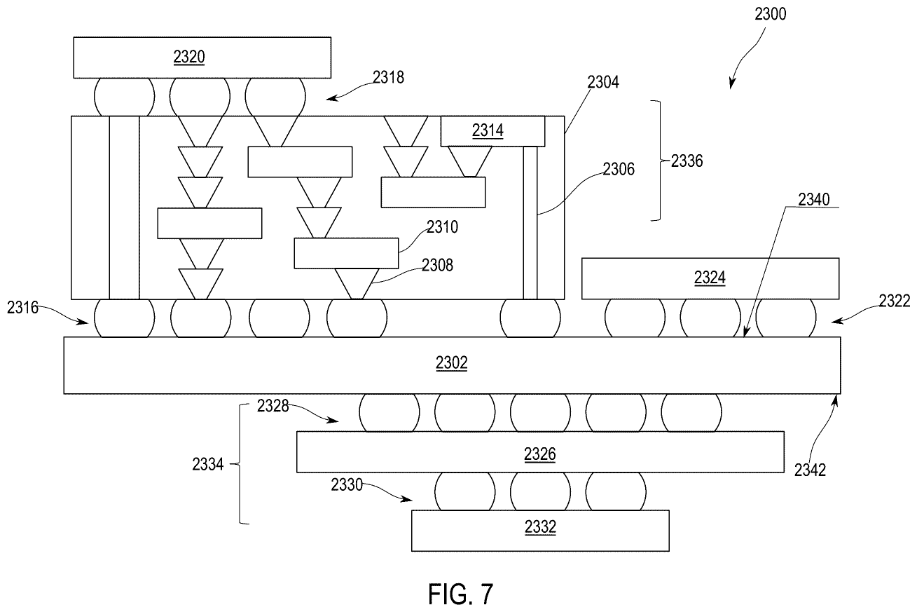

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 7.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 7 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 6.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 6. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

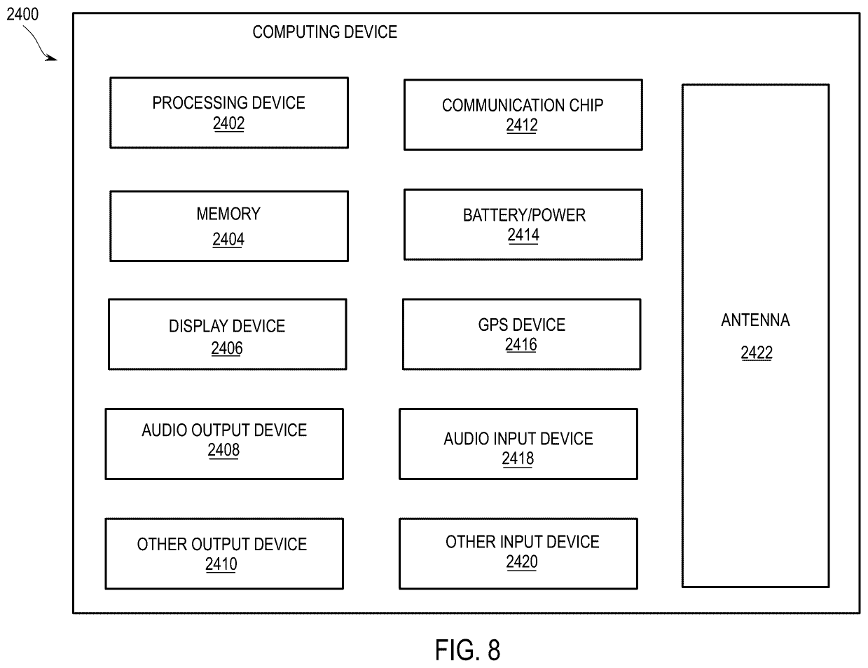

FIG. 8 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 6). In yet another example, any one or more of the components of computing device 2400 may include an IC device assembly 2300 (e.g., as shown in FIG. 7).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single system-on-chip (SOC) die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408 but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

Example 1 provides a microelectronic assembly (e.g., 100, FIG. 1), comprising: a package substrate (e.g., 102) having a core (e.g., 104) of solid continuous glass material with one or more capacitors (e.g., 110) in the solid continuous glass material; and one or more IC dies (e.g., 114) coupled to the package substrate, in which at least one of the capacitors comprises: a first tubular layer (e.g., 202) comprising a metallic material, the first tubular layer having an outer surface (e.g., 203A) and an inner surface (e.g., 203B), the outer surface in contact with the glass material; a second tubular layer (e.g., 204) concentric with the first tubular layer and in contact with the inner surface of the first tubular layer, the second tubular layer comprising a first dielectric material; a third tubular layer (e.g., 206) concentric with the second tubular layer and in contact with the second tubular layer, the third tubular layer comprising a second dielectric material; a fourth tubular layer (e.g., 208) concentric with the third tubular layer and in contact with the third tubular layer, the fourth tubular layer comprising the first dielectric material; and a fifth tubular layer (e.g., 210) concentric with the fourth tubular layer and in contact with the fourth tubular layer, the fifth tubular layer comprising the metallic material.

Example 2 provides the microelectronic assembly of example 1, in which the first dielectric material is a crystalline inorganic material and the second dielectric material is an amorphous organic material.

Example 3 provides the microelectronic assembly of any one of examples 1-2, in which the first tubular layer and the fifth tubular layer comprise at least one of: copper, iridium, a compound comprising iridium and oxygen, ruthenium, a compound comprising ruthenium and oxygen, or a compound comprising titanium and nitrogen.

Example 4 provides the microelectronic assembly of any one of examples 1-3, in which the first dielectric material comprises at least one of: a compound comprising titanium and oxygen, a compound comprising hafnium and oxygen, or a compound comprising zirconium and oxygen.

Example 5 provides the microelectronic assembly of any one of examples 1-4, in which the second dielectric material comprises at least one of: polytetrafluoroethylene (PTFE), poly (1,3,5-trimethyl-1,3,5-trivinyl cyclotrisiloxane), or poly (1,3,5,7-tetravinyl-1,3,5,7-tetramethylcyclotetrasiloxane).

Example 6 provides the microelectronic assembly of any one of examples 1-5, in which: the first dielectric material has a first dielectric constant, the second dielectric material has a second dielectric constant, and the first dielectric constant is higher than the second dielectric constant.

Example 7 provides the microelectronic assembly of any one of examples 1-6, in which: the core comprises a first surface (e.g., 216) and an opposing second surface (e.g., 218), and the at least one of the capacitors extends through a thickness (e.g., 220) of the core, contacting the first surface and the second surface.

Example 8 provides the microelectronic assembly of any one of examples 1-6, in which: the core comprises a first surface and an opposing second surface, and the at least one of the capacitors extends partially through a thickness of the core, contacting one of the first surface or the second surface.

Example 9 provides the microelectronic assembly of any one of examples 1-8, in which: the first tubular layer is conductively coupled to a first conductive structure (e.g., 212, 302) configured to operate at a first voltage, the fifth tubular layer is conductively coupled to a second conductive structure (e.g., 214) configured to operate at a second voltage, and the first conductive trace and the second conductive trace are in organic materials on at least a first side or a second side of the core, the second side being opposite to the first side.

Example 10 provides the microelectronic assembly of example 9, in which: the first conductive structure comprises an annular conductive trace overlapping the first tubular layer in plan view.

Example 11 provides a package substrate (e.g., 102, FIG. 1), comprising: a core (e.g., 104) including a solid continuous glass material, the core having a first surface (e.g., 216) and an opposing second surface (e.g., 218) and a capacitor (e.g., 110) in the solid continuous glass material; layers of a first organic dielectric material (e.g., 106A, 106B) on at least one side of the core, the layers being parallel to the first surface and the second surface; conductive traces between the layers of the first organic dielectric material, the conductive traces being parallel to the first surface and the second surface; and conductive vias through the layers of the first organic dielectric material, the conductive vias being perpendicular to the first surface and the second surface, in which: the capacitor comprises a dielectric structure between two conductive structures (e.g., 202, 210), the dielectric structure comprises a second organic dielectric material (e.g., 206) between two inorganic dielectric materials (e.g., 204, 208), and the two conductive structures are conductively coupled to the conductive traces.

Example 12 provides the package substrate of example 11, further comprising a plurality of the capacitor in the solid continuous glass material.

Example 13 provides the package substrate of any one of examples 11-12, in which the layers of the first organic dielectric material, the conductive traces and the conductive vias are further on either side of the core.

Example 14 provides the package substrate of example 13, further comprising: conductive TGVs (e.g., 112) in the solid continuous glass material, the TGVs being conductively coupled to the conductive traces on either side of the core.

Example 15 provides the package substrate of example 13, in which (e.g., FIG. 2) the capacitor extends through an entire thickness of the core.

Example 16 provides the package substrate of example 11, in which (e.g., FIG. 3) the capacitor extends partially through a thickness of the core.

Example 17 provides the package substrate of any one of examples 11-16, in which (e.g., FIG. 2): at least one of the conductive traces (e.g., 212) is on the first surface of the core, at least one of the conductive vias (e.g., 214) is on the first surface of the core, the at least one of the conductive traces is conductively coupled to one (e.g., 202) of the two conductive structures of the capacitor, and the at least one of the conductive vias is conductively coupled to the other (e.g., 210) of the two conductive structures of the capacitor.

Example 18 provides the package substrate of example 17, in which: the one of the two conductive structures is a tube, another of the two conductive structures is a cylinder that is not hollow, the tube and the cylinder are concentric with respect to each other, the cylinder being within the tube and separated from the tube by the dielectric structure, the at least one of the conductive traces comprises an annular ring in direct contact with the tube, and the at least one of the conductive vias is in direct contact with the cylinder.

Example 19 provides the package substrate of any one of examples 11-16, in which (e.g., FIG. 3): at least one of the conductive vias (e.g., 212) is on the first surface of the core, at least another of the conductive vias (e.g., 214) is on the first surface of the core, the at least one of the conductive vias is conductively coupled to one (e.g., 202) of the two conductive structures of the capacitor, and the at least another of the conductive vias is conductively coupled to the other (e.g., 210) of the two conductive structures of the capacitor.

Example 20 provides a capacitor structure, comprising: a first conductive structure of a metallic material; a second conductive structure of the metallic material; and a dielectric structure between the first conductive structure and the second conductive structure, in which the dielectric structure comprises: a first layer of crystalline inorganic material; a second layer of the crystalline inorganic material; and a layer of amorphous organic dielectric material between the first layer and the second layer.

Example 21 provides the capacitor structure of example 20, in which: the first conductive structure is a first tube having a first outer sidewall and a first inner sidewall, the first layer of crystalline inorganic material is a second tube concentric with the first tube, the second tube having a second outer sidewall and a second inner sidewall, the second outer sidewall in direct contact with the first inner sidewall, the layer of organic dielectric material is a third tube concentric with the first tube, the third tube having a third outer sidewall and a third inner sidewall, the third outer sidewall in direct contact with the second inner sidewall, the second layer of the crystalline inorganic materials is a fourth tube concentric with the first tube, the fourth tube having a fourth outer sidewall and a fourth inner sidewall, the fourth outer sidewall in direct contact with the third inner sidewall, the second conductive structure is a solid structure concentric with the first tube, the solid structure having a fifth outer sidewall in direct contact with the fourth inner sidewall.

Example 22 provides the capacitor structure of example 21, in which: the first, second, third and fourth tubes have respective annular cross-sections in a plan view, and the solid structure has a circular cross-section in the plan view.

Example 23 provides the capacitor structure of any one of examples 21-22, in which the first, second, third and fourth tubes have respective U-shaped cross-sections in a side view.

Example 24 provides the capacitor structure of any one of examples 20-23, in which: the capacitor structure is surrounded in plan view by a glass material, and the first conductive structure is in direct contact with the glass material.

Example 25 provides the capacitor structure of any one of examples 20-24, in which the dielectric structure has a thickness of approximately between 20 nanometers and 50 nanometers and a capacitor length in a direction perpendicular to the thickness of approximately between 0.1 millimeters and 0.25 millimeters.

Example 26 provides a method, comprising: providing a glass panel with cavities, the glass panel having a top surface and a bottom surface; depositing a first layer of metallic material on the glass panel so as to conformally coat the top surface, the bottom surface and surfaces of the cavities; depositing a second layer of inorganic dielectric material over the first layer; depositing a third layer of organic dielectric material over the second layer; depositing a fourth layer of the inorganic dielectric material over the third layer; depositing a fifth layer of the metallic material over the fourth layer so as to fill the cavities completely; and planarizing surfaces of the glass panel such that none of the metallic material, the inorganic dielectric material or the organic dielectric material coats the top surface or the bottom surface of the glass panel.

Example 27 provides the method of example 26, in which the first layer, the second layer and the fourth layer are deposited by ALD.

Example 28 provides the method of any one of examples 26-27, in which the third layer is deposited by initiated chemical vapor deposition (iCVD).

Example 29 provides the method of example 26, in which the first layer, second layer, the third layer and the fourth layer are deposited using a single iCVD/ALD deposition system in a common reactor.

Example 30 provides the method of any one of examples 26-29, in which the fifth layer of metallic material is deposited by electroplating.

Example 31 provides the method of any one of examples 26-30, in which the surfaces of the glass panel are planarized by chemical mechanical polishing.

Example 32 provides the method of any one of examples 26-31, in which the metallic material comprises at least one of: copper, iridium, a compound comprising iridium and oxygen, ruthenium, a compound comprising ruthenium and oxygen, or a compound comprising titanium and nitrogen.

Example 33 provides the method of any one of examples 26-32, in which the inorganic dielectric material comprises at least one of: a compound comprising titanium and oxygen, a compound comprising hafnium and oxygen, or a compound comprising zirconium and oxygen.

Example 34 provides the method of any one of examples 26-33, in which the organic dielectric material comprises at least one of: polytetrafluoroethylene (PTFE), poly (1,3,5-trimethyl-1,3,5-trivinyl cyclotrisiloxane), or poly(1,3,5,7-tetravinyl-1,3,5,7-tetramethylcyclotetrasiloxane).

Example 35 provides the method of any one of examples 26-34, further comprising activating a monomer of the organic dielectric material on a surface of the second layer with a thermally activated initiator radical to polymerize the organic dielectric material.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a package substrate having a core of solid continuous glass material with one or more capacitors in the solid continuous glass material; and
one or more integrated circuit (IC) dies coupled to the package substrate,
wherein at least one of the capacitors comprises:
a first tubular layer comprising a metallic material, the first tubular layer having an outer surface and an inner surface, the outer surface in contact with the glass material;
a second tubular layer concentric with the first tubular layer and in contact with the inner surface of the first tubular layer, the second tubular layer comprising a first dielectric material;
a third tubular layer concentric with the second tubular layer and in contact with the second tubular layer, the third tubular layer comprising a second dielectric material;
a fourth tubular layer concentric with the third tubular layer and in contact with the third tubular layer, the fourth tubular layer comprising the first dielectric material; and
a fifth tubular layer concentric with the fourth tubular layer and in contact with the fourth tubular layer, the fifth tubular layer comprising the metallic material.

2. The microelectronic assembly of claim 1, wherein the first dielectric material is a crystalline inorganic material and the second dielectric material is an amorphous organic material.

3. The microelectronic assembly of claim 1, wherein the first tubular layer and the fifth tubular layer comprise at least one of: copper, iridium, a compound comprising iridium and oxygen, ruthenium, a compound comprising ruthenium and oxygen, or a compound comprising titanium and nitrogen.

4. The microelectronic assembly of claim 1, wherein the first dielectric material comprises at least one of: a compound comprising titanium and oxygen, a compound comprising hafnium and oxygen, or a compound comprising zirconium and oxygen.

5. The microelectronic assembly of claim 1, wherein the second dielectric material comprises at least one of: polytetrafluoroethylene (PTFE), poly (1,3,5-trimethyl-1,3,5-trivinyl cyclotrisiloxane), or poly (1,3,5,7-tetravinyl-1,3,5,7-tetramethylcyclotetrasiloxane).

6. The microelectronic assembly of claim 1, wherein:
the first dielectric material has a first dielectric constant,
the second dielectric material has a second dielectric constant, and
the first dielectric constant is higher than the second dielectric constant.

7. The microelectronic assembly of claim 1, wherein:
the core comprises a first surface and an opposing second surface, and
the at least one of the capacitors extends through a thickness of the core, contacting the first surface and the second surface.

8. The microelectronic assembly of claim 1, wherein:
the core comprises a first surface and an opposing second surface, and
the at least one of the capacitors extends partially through a thickness of the core, contacting one of the first surface or the second surface.

9. The microelectronic assembly of claim 1, wherein:
the first tubular layer is conductively coupled to a first conductive structure configured to operate at a first voltage,
the fifth tubular layer is conductively coupled to a second conductive structure configured to operate at a second voltage, and
the first conductive trace and the second conductive trace are in organic materials on at least a first side or a second side of the core, the second side being opposite to the first side.

10. The microelectronic assembly of claim 9, wherein: the first conductive structure comprises an annular conductive trace overlapping the first tubular layer in plan view.

11. A package substrate, comprising:
a core including a solid continuous glass material, the core having a first surface and an opposing second surface and a capacitor in the solid continuous glass material;
layers of a first organic dielectric material on at least one side of the core, the layers being parallel to the first surface and the second surface;
conductive traces between the layers of the first organic dielectric material, the conductive traces being parallel to the first surface and the second surface; and
conductive vias through the layers of the first organic dielectric material, the conductive vias being perpendicular to the first surface and the second surface,
wherein:
the capacitor comprises a dielectric structure between two conductive structures,
the dielectric structure comprises a second organic dielectric material between two inorganic dielectric materials, and
the two conductive structures are conductively coupled to the conductive traces.

12. The package substrate of claim 11, wherein the layers of the first organic dielectric material, the conductive traces and the conductive vias are further on either side of the core.

13. The package substrate of claim 12, further comprising: conductive through-glass vias (TGVs) in the solid continuous glass material, the TGVs being conductively coupled to the conductive traces on either side of the core.

14. The package substrate of claim 11, wherein:
at least one of the conductive traces is on the first surface of the core,
at least one of the conductive vias is on the first surface of the core,
the at least one of the conductive traces is conductively coupled to one of the two conductive structures of the capacitor, and
the at least one of the conductive vias is conductively coupled to the other of the two conductive structures of the capacitor.

15. The package substrate of claim 14, wherein:
the one of the two conductive structures is a tube,
another of the two conductive structures is a cylinder that is not hollow,
the tube and the cylinder are concentric with respect to each other, the cylinder being within the tube and separated from the tube by the dielectric structure,
the at least one of the conductive traces comprises an annular ring in direct contact with the tube, and
the at least one of the conductive vias is in direct contact with the cylinder.

16. The package substrate of claim 11, wherein:
at least one of the conductive vias is on the first surface of the core,
at least another of the conductive vias is on the first surface of the core,
the at least one of the conductive vias is conductively coupled to one of the two conductive structures of the capacitor, and
the at least another of the conductive vias is conductively coupled to the other of the two conductive structures of the capacitor.

17. A capacitor structure, comprising:
a first conductive structure of a metallic material;
a second conductive structure of the metallic material; and
a dielectric structure between the first conductive structure and the second conductive structure,
wherein the dielectric structure comprises:
a first layer of crystalline inorganic material;
a second layer of the crystalline inorganic material; and
a layer of amorphous organic dielectric material between the first layer and the second layer.

18. The capacitor structure of claim 17, wherein:
the first conductive structure is a first tube having a first outer sidewall and a first inner sidewall,
the first layer of crystalline inorganic material is a second tube concentric with the first tube, the second tube having a second outer sidewall and a second inner sidewall, the second outer sidewall in direct contact with the first inner sidewall,
the layer of organic dielectric material is a third tube concentric with the first tube, the third tube having a third outer sidewall and a third inner sidewall, the third outer sidewall in direct contact with the second inner sidewall,
the second layer of the crystalline inorganic materials is a fourth tube concentric with the first tube, the fourth tube having a fourth outer sidewall and a fourth inner sidewall, the fourth outer sidewall in direct contact with the third inner sidewall,
the second conductive structure is a solid structure concentric with the first tube, the solid structure having a fifth outer sidewall in direct contact with the fourth inner sidewall.

19. The capacitor structure of claim 18, wherein:
the first, second, third and fourth tubes have respective annular cross-sections in a plan view, and
the solid structure has a circular cross-section in the plan view.

20. The capacitor structure of claim 18, wherein the first, second, third and fourth tubes have respective U-shaped cross-sections in a side view.
